(19) United States
(12) Patent Application Publication
(10) Pub. No.: US 2025/0347999 A1
(43) Pub. Date: Nov. 13, 2025

(54) PHOTORESIST COMPOSITIONS, AND METHODS OF MANUFACTURING SEMICONDUCTOR DEVICES USING THE SAME

(71) Applicant: Samsung Electronics Co., Ltd., Suwon-si (KR)

(72) Inventors: Sounghyun Jun, Suwon-si (KR); Juhyeon Park, Suwon-si (KR)

(21) Appl. No.: 19/077,639

(22) Filed: Mar. 12, 2025

(30) Foreign Application Priority Data
May 7, 2024 (KR) 10-2024-0059886

(51) Int. Cl. G03F 7/039; G03F 7/00; G03F 7/36; H01L 21/027; H01L 21/308; H01L 21/311; H01L 21/3213

(52) U.S. Cl. CPC G03F 7/039; G03F 7/36; G03F 7/70025; H01L 21/0275; H01L 21/0276; H01L 21/3081; H01L 21/3086; H01L 21/31144; H01L 21/32139

(57) ABSTRACT

Provided is a photoresist composition including a photosensitive polymer having a main chain including a polyester group, a photoacid generator (PAG), and a solvent. Photoresist compositions may also include a photo-decomposable quencher. Methods of manufacturing semiconductor devices comprising a photoresist composition are also provided, which can be devoid of a developing process.

### CROSS-REFERENCE TO RELATED APPLICATION

This application is based on and claims priority under 35 U.S.C. § 119 to Korean Patent Application No. 10-2024-0059886, filed May 7, 2024, in the Korean Intellectual Property Office, the disclosure of which is incorporated by reference herein in its entirety.

### FIELD

The inventive concept relates to a photoresist composition and a method of manufacturing a semiconductor device using the same, and more particularly, to a photoresist composition including a photosensitive polymer having a main chain including a polyester group and a method of manufacturing a semiconductor device using the same.

### BACKGROUND

Due to the development of electronics technology, recently, down-scaling of semiconductor devices has progressed rapidly. Accordingly, a photolithography process using extreme ultraviolet (EUV) light, which is advantageous for implementing fine patterns, has been proposed. When the development process is performed using an aqueous developer in the EUV photolithography process, there is a problem of pattern collapse due to the aqueous developer or pattern defects by particles, etc. caused by the aqueous developer, so a solution to this problem is required.

### SUMMARY

In some embodiments, the inventive concept provides a photoresist composition capable of preventing pattern collapse by an aqueous developer or a pattern defect by particles caused by the aqueous developer, and a method of manufacturing a semiconductor device using the same.

According to an aspect of the inventive concept, there is provided a photoresist composition including a photosensitive polymer having a main chain including a polyester group, a photoacid generator (PAG), and a solvent.

According to an aspect of the inventive concept, there is provided a method of manufacturing a semiconductor device, the method including forming a photoresist film on a feature layer using a photoresist composition including a photosensitive polymer having a main chain including a polyester group, a photoacid generator (PAG), and a solvent, exposing a first region that is part of the photoresist film, removing the exposed region of the photoresist film by baking the photoresist film and forming a photoresist pattern including an unexposed region of the photoresist film; and processing the feature layer using the photoresist pattern.

According to an aspect of the inventive concept, there is provided a photoresist composition including a photosensitive polymer having a main chain including a polyester group, a photoacid generator (PAG), a solvent, and a photo-decomposable quencher (PDQ).

### BRIEF DESCRIPTION OF THE DRAWINGS

Embodiments will be more clearly understood from the following detailed description taken in conjunction with the accompanying drawings in which:

FIG. 1 is a diagram showing a thickness of each photoresist film remaining after exposing using EUV light and baking using a photoresist film formed using a photoresist composition according to embodiments and a photoresist film formed using a photoresist composition according to a comparative example;

FIG. 2 is a flowchart illustrating a method of manufacturing a semiconductor device according to embodiments; and

FIGS. 3 to 7 are cross-sectional views to explain each process of the method of manufacturing a semiconductor device according to embodiments.

### DETAILED DESCRIPTION OF THE EMBODIMENTS

Hereinafter, embodiments of the inventive concept will be described in detail with reference to the accompanying drawings. Like reference numerals are used for the like element in the drawings, and duplicate descriptions thereof are omitted.

A photoresist composition according to embodiments may include a photosensitive polymer having a main chain including a polyester group, a photoacid generator (PAG), and a solvent.

In some embodiments, the photosensitive polymer may include repeating units represented by Formula 1 below.

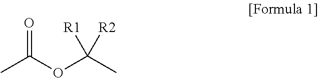

In Formula 1, R1 and R2 may each independently be a C1 to C5 alkyl group, a C2 to C5 alkenyl group or a phenyl group, or may be connected to each other to form a C3 to C6 cycloalkyl group.

In example embodiments, the photosensitive polymer may include repeating units represented by Formula 2 below.

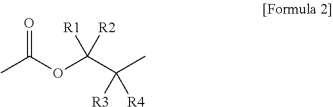

In Formula 2, R1, R2, R3 and R4 may each independently be a C1 to C5 alkyl group, a C2 to C5 alkenyl group or a phenyl group, and R1 and R2 may be connected to each other to form a C3 to C6 cycloalkyl group, and/or R3 and R4 may be connected to each other to form a C3 to C6 cycloalkyl group.

In example embodiments, the photosensitive polymer may include repeating units represented by Formula 3 below.

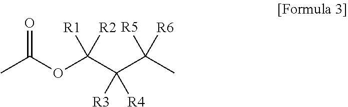

In Formula 3, R1, R2, R3, R4, R5 and R6 may each independently be a C1 to C5 alkyl group, a C2 to C5 alkenyl group or a phenyl group, and R1 and R2 may be connected to each other to form a C3 to C6 cycloalkyl group, R3 and R4 may be connected to each other to form a C3 to C6 cycloalkyl group, and/or R5 and R6 may be connected to each other to form a C3 to C6 cycloalkyl group.

In example embodiments, the photosensitive polymer may include any one structure selected from the following structures.

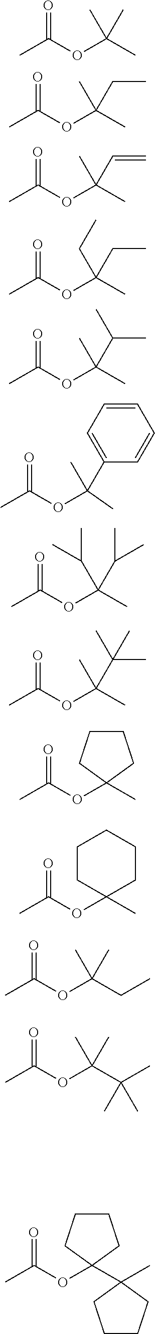

In the photoresist composition according to embodiments, the content of the photosensitive polymer may be in an amount range from about 0.5 wt % to about 10 wt %, e.g., 0.5 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, 10 wt %, based on the total weight of the photoresist composition, or any range therein, but is not limited thereto.

In the photoresist composition according to embodiments, the photosensitive polymer may include 10 to 10,000 repeating units, e.g., 10, 100, 500, 1000, 2000, 3000, 4000, 5000, 6000, 7000, 8000, 9000, or 10000, or any range therein.

In the photoresist composition according to embodiments, a weight average molecular weight (Mw) of the photosensitive polymer may be 1,000 to 1,000,000, e.g., 1,000, 10,000, 100,000, of 1,000,000, or any range therein.

The PAG included in the photoresist composition according to embodiments may be a material that generates acid when exposed to at least one type of light selected from a KrF excimer laser (248 nm), an ArF excimer laser (193 nm), an F₂ excimer laser (157 nm), and an EUV laser (13.5 nm). The PAG may include a material that generates a relatively strong acid having a pKa (acid dissociation constant) of about −20 or more and less than about 1, e.g., −20, −18, −16, −14, −12, −10, −8, −6, −4, −2, 0, 1, or any range therein, when exposed to light.

In example embodiments, the PAG may include triarylsulfonium salts, diaryliodonium salts, sulfonates, or any mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris (alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or any mixture thereof.

In the photoresist composition according to embodiments, the PAG may be included in an amount range from about 10 wt % to about 70 wt %, e.g., 10 wt %, 20 wt %, 30 wt %, 40 wt %, 50wt %, 60 wt %, 70 wt %, based on the total weight of the photosensitive polymer, or any range therein, but is not limited thereto.

In the photoresist composition according to embodiments, the solvent may be an organic solvent. In example embodiments, the solvent may include at least one of ether, alcohol, glycol ether, aromatic hydrocarbon compound, ketone, and ester. For example, the solvent may be selected from among ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, etc. These solvents may be used alone or in any combination of at least two types.

In example embodiments, the photoresist composition may further include a photo-decomposable quencher (PDQ).

The PDQ may trap acid generated from the PAG included in the photoresist composition according to some embodiments in a non-exposed region of the photoresist film when the acid diffuses into the non-exposed region. Because the basic quencher is included in the photoresist composition according to some embodiments, after exposing the photoresist film obtained from the photoresist composition, problems caused by acid generated in the exposed region of the photoresist film due to diffusing into the non-exposed region of the photoresist film may be prevented.

In example embodiments, the PDQ may include a primary aliphatic amine, a secondary aliphatic amine, a tertiary aliphatic amine, an aromatic amine, a heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof, but is not limited to the above examples.

In some example embodiments, the PDQ may include a photodegradable base. The photodegradable base may include a compound that generates acid by exposure and neutralizes the acid before exposure. In some embodiments, when the photodegradable base is decomposed by exposure, the photodegradable base may lose its ability to trap acid. Accordingly, if a partial region of a photoresist film formed from a photoresist composition including PDQ consisting of the photodegradable base is exposed, the photodegradable base loses alkalinity in the exposed region of the photoresist film and the photodegradable base traps acid in the unexposed region of the photoresist film. Thus, in some embodiments, problems that may be caused by acid generated in the exposed region of the photoresist film due to diffusing into the non-exposed region of the photoresist film may be prevented.

The photodegradable base may include a carboxylate or sulfonate salt of a photodegradable cation. For example, the photodegradable cation may form a complex with anion of a C1-C20 carboxylic acid. The carboxylic acid may include, for example, formic acid, acetic acid, propionic acid, tartaric acid, succinic acid, cyclohexylcarboxylic acid, benzoic acid, or salicylic acid, but is not limited thereto.

In the photoresist composition according to embodiments, the PDQ may be included in an amount from about 5 wt % to about 50 wt % based on the total weight of the photosensitive polymer, e.g., 5 wt %, 10 wt %, 15 wt %, 20 wt %, 25 wt %, 30 wt %, 35 wt %, 40 wt %, 45 wt %, 50 wt %, or any range therein, but is not limited thereto.

In the photoresist composition according to embodiments, the solvent may be included in the remaining amount excluding the content of the main components including the photosensitive polymer and the PAG. In example embodiments, the solvent may be included in an amount from about 0.1 wt % to about 99.0 wt %, e.g., 0.1 wt %, 1 wt %, 5 wt %, 10 wt %, 15 wt %, 20 wt %, 25wt %, 30 wt %, 35 wt %, 40 wt %, 45 wt %, 50 wt %, 55 wt %, 60 wt %, 65 wt %, 70 wt %, 75 wt %, 80wt %, 85 wt %, 90 wt %, 95 wt %, 97 wt %, 98 wt %, or 99 wt %, based on the total weight of the photoresist composition, or any range therein.

In example embodiments, the photoresist composition may further include at least one selected from a surfactant, a dispersant, and a coupling agent.

In some embodiments, the surfactant may improve coating uniformity and wettability of the photoresist composition. In example embodiments, the surfactant may include a sulfuric acid ester salt, a sulfonate salt, a phosphate ester, a soap, an amine salt, a quaternary ammonium salt, polyethylene glycol, an alkylphenolethylene oxide adduct, a polyhydric alcohol, a nitrogen-containing vinyl polymer, or any combination thereof but is not limited to these materials. For example, the surfactant may include alkylbenzenesulfonate, alkylpyridinium salt, polyethylene glycol, or quaternary ammonium salt. If the photoresist composition includes the surfactant, the surfactant may be included in an amount from about 0.001 wt % to about 3 wt %, e.g., 0.001 wt %, 0.01 wt %, 0.1 wt %, 0.5 wt %, 1 wt %, 2 wt %, or 3 wt %, based on the total weight of the photoresist composition, or any range therein.

In some embodiments, the dispersion agent may serve to uniformly disperse each component constituting the photoresist composition within the photoresist composition. In example embodiments, the dispersant may include epoxy resin, polyvinyl alcohol, polyvinyl butyral, polyvinylpyrrolidone, glucose, sodium dodecyl sulfate, sodium citrate, oleic acid, linoleic acid, or any combination thereof but is not limited to these materials. If the photoresist composition includes the dispersant, the dispersant may be included in an amount of about 0.001 wt % to about 5 wt %, e.g., 0.001 wt %, 0.01 wt %, 0.1 wt %, 0.5 wt %, 1 wt %, 2 wt %, 3 wt %, 4 wt %, or 5 wt %, based on the total weight of the photoresist composition, or any range therein.

In some embodiments, the coupling agent may improve adhesion to a lower film when coating the photoresist composition on the lower film. In example embodiments, the coupling agent may include a silane coupling agent. The silane coupling agent may include vinyltrimethoxysilane, vinyltriethoxysilane, vinyl trichlorosilane, vinyltris (β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy [3-(phenylamino)propyl]silane, but is not limited to these materials. If the photoresist composition includes the coupling agent, the coupling agent may be included in an amount of about 0.001 wt % to about 5 wt %, e.g., 0.001 wt %, 0.01 wt %, 0.1 wt %, 0.5 wt %, 1 wt %, 2 wt %, 3 wt %, 4 wt %, or 5 wt %, based on the total weight of the photoresist composition, or any range therein.

In the photoresist composition according to embodiments of the inventive concept, if the solvent includes only an organic solvent, the photoresist composition may further include water. In this case, the water content in the photoresist composition may be in a range from about 0.001wt % to about 0.1 wt %, e.g., 0.001 wt %, 0.005 wt %, 0.01 wt %, 0.015 wt %, 0.020 wt %, 0.025 wt %, 0.03 wt %, 0.035 wt %, 0.04 wt %, 0.045 wt %, 0.05 wt %, 0.055 wt %, 0.06 wt %, 0.065 wt %, 0.07wt %, 0.075 wt %, 0.08 wt %, 0.085 wt %, 0.09 wt %, 0.095 wt %, or 0.1 wt %, or any range therein.

In example embodiments, the photoresist composition may be a photoresist composition for EUV photolithography.

The photoresist composition according to example embodiments may include a photosensitive polymer having a main chain including a polyester group. Unlike conventional photoresist compositions, the polyester group included in the main chain of the photosensitive polymer of the photoresist composition according to example embodiments may be decomposed and vaporized through a baking process after exposure. Accordingly, if the photoresist composition according to example embodiments is used, a photoresist pattern may be formed without a developing process, e.g., devoid of a developing process. Because the development process is omitted, it is possible to prevent the photoresist pattern from collapsing by the developer or the occurrence of defects in the photoresist pattern by particles caused by the developer.

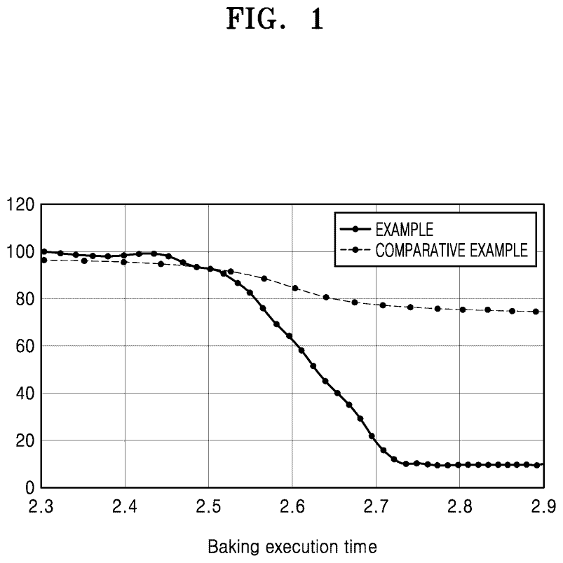

FIG. 1 is a diagram showing a thickness of each photoresist film remaining after exposing using EUV light and baking using a photoresist film formed using a photoresist composition according to embodiments and a photoresist film formed using a photoresist composition according to a comparative example.

In FIG. 1, a photoresist composition according to example embodiments may include a photosensitive polymer including a repeating unit represented by Formula 4, PAG represented by Formula 5, PDQ represented by Formula 6, and propylene glycol methyl ether acetate as a solvent, and a photoresist composition according to the comparative example may include a photosensitive polymer including a repeating unit represented by Formula 7, PAG represented by Formula 5,PDQ represented by Formula 6, and propylene glycol methyl ether acetate as a solvent.

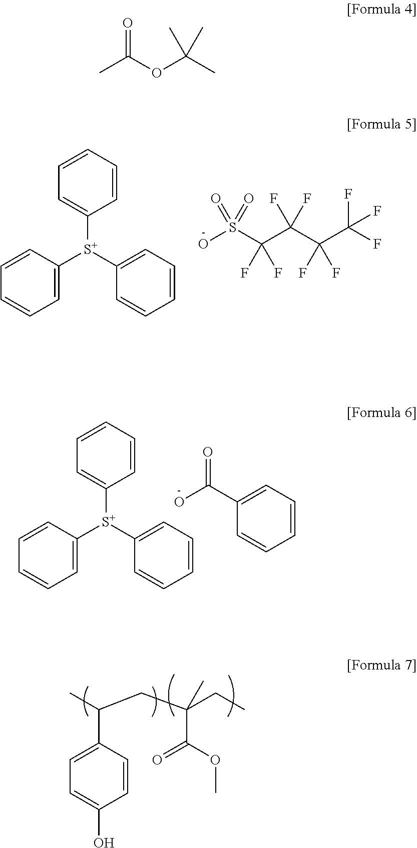

In FIG. 1, the Y axis represents a value of a thickness after baking divided by the thickness before baking and multiplied by 100 for each of a photoresist film formed using the photoresist composition according to example embodiments and a photoresist film formed using the photoresist composition according to comparative example, and the X-axis represents a baking execution time.

Referring to FIG. 1, it may be seen that, in the photoresist film formed using the photoresist composition according to the comparative example, 70% of the thickness of the photoresist film before exposure and baking remains even after baking. In contrast, in the photoresist film formed using the photoresist composition according to example embodiments, only 10% of the thickness of the photoresist film before exposure and baking remains after baking. That is, considering the results of FIG. 1, most of the photoresist film formed using the photoresist composition according to the comparative example remains, even when baking is performed after exposure to EUV light, and the reduction of the thickness of the photoresist film formed using the photoresist composition according to the comparative example by the exposure and baking process may be assumed due to a shrink phenomenon that occurs during the exposure and baking process. On the other hand, it may be confirmed that the photoresist film formed using the photoresist composition according to example embodiments is removed by being decomposed and vaporized by baking after exposure to EUV light.

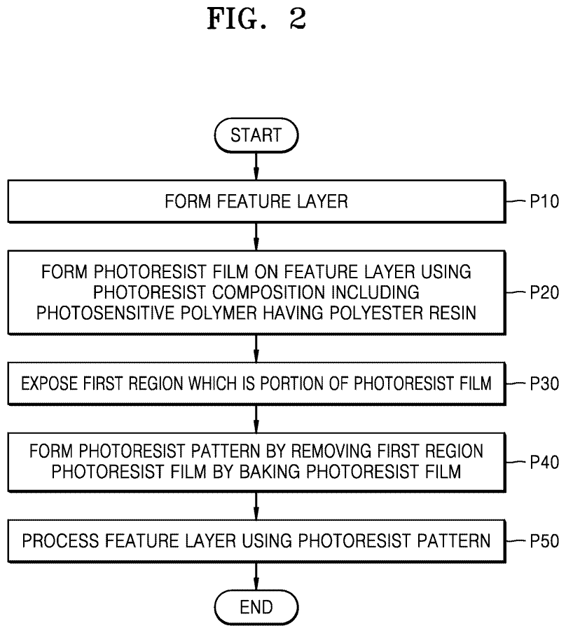

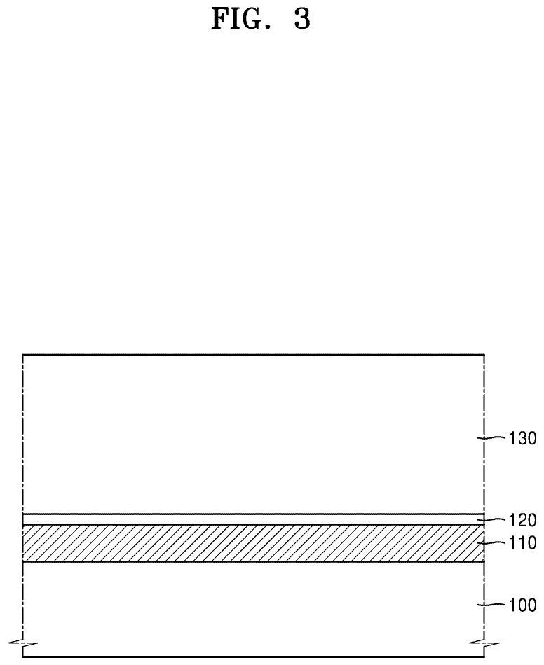

FIG. 2 is a flowchart illustrating a method of manufacturing a semiconductor device according to embodiments. FIGS. 3 to 7 are cross-sectional views to explain each process of the method of manufacturing a semiconductor device according to example embodiments.

Referring to FIGS. 2 and 3, a feature layer 110 may be formed on a substrate 100 (P10), and a photoresist film 130 may be formed on the feature layer 110 using a photoresist composition according to example embodiments (P20).

The photoresist film 130 may include a photoresist composition including a photosensitive polymer having a main chain including a polyester group, and the detailed structure of the photoresist composition may be the same as described above.

The substrate 100 may include a semiconductor substrate. For example, the substrate 100 may include an elemental semiconductor material, such as Si or Ge, or a compound semiconductor material, such as SiGe, SiC, GaAs, InAs, or InP.

The feature layer 110 may include an insulating film, a conductive film, or a semiconductor film. For example, the feature layer 110 may include a metal, an alloy, metal carbide, metal nitride, metal oxynitride, metal oxycarbide, semiconductor, polysilicon, oxide, nitride, oxynitride, or any combination thereof but is not limited thereto.

In example embodiments, as illustrated in FIG. 3, a lower film 120 may be formed on the feature layer 110 before forming the photoresist film 130 on the feature layer 110. In this case, the photoresist film 130 may be formed on the lower film 120. The lower film 120 may control irregular reflection of light from a light source used during an exposure process for manufacturing a semiconductor device or may absorb reflected light from the lower feature layer 110.

In example embodiments, the lower film 120 may include an organic or inorganic anti-reflective coating (ARC) material for a KrF excimer laser, an ArF excimer laser, an EUV laser, or any other light source. In example embodiments, the lower film 120 may include a bottom anti-reflective coating (BARC) film or a developable bottom anti-reflective coating (DBARC) film.

In other example embodiments, the lower film 120 may include an organic component having a light absorption structure. The light absorption structure may be, for example, a hydrocarbon compound having one or more benzene rings or a structure in which benzene rings are fused. The lower film 120 may be formed to have a thickness in a range from about 20 nm to about 100 nm, e.g., 20 nm, 30 nm, 40 nm, 50 nm, 60 nm, 70 nm, 80 nm, or 100 nm, or any range therein, but is not limited thereto. In example embodiments, the lower film 120 may be omitted.

To form the photoresist film 130, the photoresist composition according to example embodiments may be coated on the lower film 120 and then heat treated. The coating may include a spin coating, a spray coating, and a dip coating. The process of heat treating the photoresist composition may be performed at a temperature in a range from about 80° C. to about 300° C., e.g., 80° C., 100° C., 120° C., 140° C., 160° C., 180° C., 200° C., 220° C., 240° C., 260° C., 280° C., or 300° C., or any range therein, for about 10 seconds to about 100 seconds, 10 nm, 20 nm, 30 nm, 40 nm, 50 nm, 60 nm, 70 nm, 80 nm, 90 nm, or 100 nm, or any range therein, but is not limited thereto. The thickness of the photoresist film 130 may be tens to hundreds of times the thickness of the lower film 120. The photoresist film 130 may be formed to have a thickness in a range from about 100 nm to about 6 μm, e.g., 100 nm, 500 nm, 1000 nm, 2.5 μm, 5 μm or 6 μm, or any range therein, but is not limited thereto.

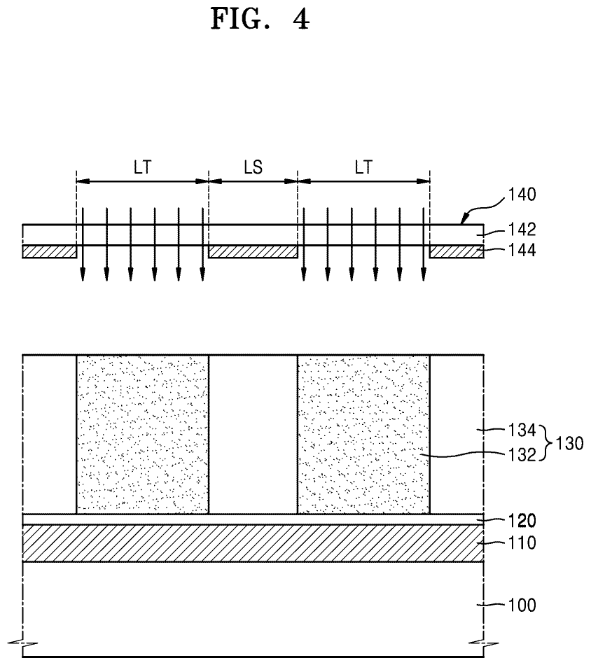

Referring to FIGS. 2 and 4, a first region 132, which is a portion of the photoresist film 130, may be exposed (P30).

In example embodiments, to expose the first region 132 of the photoresist film 130, a photomask 140 having a plurality of light shielding areas LS and a plurality of light transmitting areas LT is aligned at a predetermined position on the photoresist film 130, and the first region 132 of the photoresist film 130 may be exposed through the plurality of light transmitting areas LT of the photomask 140. In example embodiments, an EUV laser (13.5 nm) may be used to expose the first region 132 of the photoresist film 130.

The photomask 140 may include a transparent substrate 142 and a plurality of light shielding patterns 144 formed in the plurality of light shielding areas LS on the transparent substrate 142. The transparent substrate 142 may include quartz. The plurality of light shielding patterns 144 may include chrome (Cr). A plurality of light transmitting areas LT may be defined by a plurality of light shielding patterns 144. According to example embodiments, a reflective photomask (not shown) for EUV exposure may be used instead of the photomask 140 to expose the first region 132 of the photoresist film 130.

In example embodiments, after performing operation P20 of FIG. 2 and before performing operation P30 of FIG. 2, the photoresist layer 130 may be soft baked. The soft baking may be performed at a temperature in a range from about 50° C. to about 100° C., e.g., 50° C., 60° C., 70° C., 80° C., 90° C., or 100° C., or any range therein, for about 5 minutes to about 10 minutes, e.g., 5minutes, 6 minutes, 7 minutes, 8 minutes, 9 minutes, or 10 minutes, or any range therein, but is not limited thereto.

In example embodiments, after exposing the first region 132 of the photoresist film 130 according to operation P30 of FIG. 2, the photoresist film 130 may be annealed. The annealing may be performed at a temperature in a range from about 50° C. to about 400° C., e.g., 50° C., 60° C., 70° C., 80° C., 90° C., 100° C., 110° C., 120° C., 130° C., 140° C., 150° C., 160° C., 170° C., 180° C., 190° C., 200° C., 210° C., 220° C., 230° C., 240° C., 250° C., 260° C., 270° C., 280° C., 290° C., 300° C., 310° C., 320° C., 330° C., 340° C., 350° C., 360° C., 370° C., 380° C., 390° C., or 400° C., or any range therein, for about 10 seconds to about 100 seconds, e.g., 10 seconds, 20 seconds, 30 seconds, 40 seconds, 50 seconds, 60 seconds, 70 seconds, 80 seconds, 90 seconds, or 100 seconds, or any range therein, but is not limited thereto.

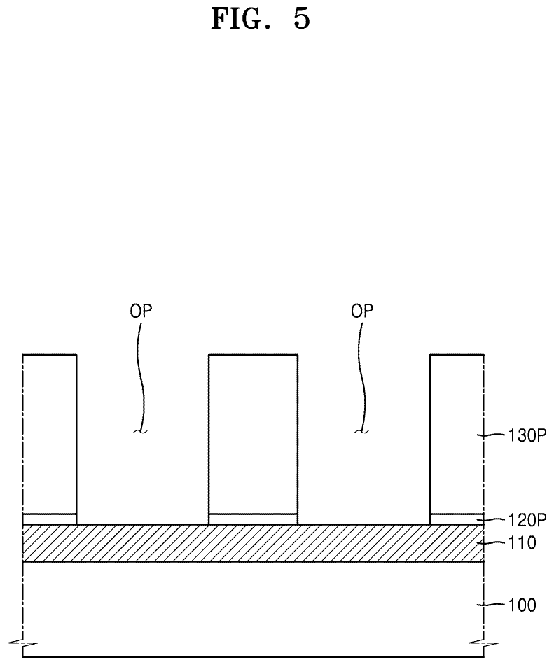

Referring to FIGS. 2 and 5, the first region 132 of the photoresist film 130 may be removed by baking the photoresist film 130 (P40). As a result, a photoresist pattern 130P including an unexposed second region 134 (refer FIG. 4) of the photoresist film 130 may be formed.

As described above, the photoresist composition forming the photoresist film 130 may include a photosensitive polymer having a main chain including a polyester group, and the polyester group in the exposed first region 132 is decomposed by baking and may be vaporized.

In example embodiments, operation P40 may be performed at a temperature in a range from about 100° C. to about 180° C., e.g., 100° C., 110° C., 120° C., 130° C., 140° C., 150° C., 160° C., 170° C., or 180° C., or any range therein, for about 10 seconds to about 10 minutes, e.g., 10 seconds, 20 seconds, 30 seconds, 40 seconds, 50 seconds, 60 seconds, 2 minutes, 3 minutes, 4 minutes, 5 minutes, 6 minutes, 7 minutes, 8 minutes, 9 minutes or 10 minutes, or any time range therein, but is not limited thereto.

The photoresist pattern 130P may include a plurality of openings OP. After the photoresist pattern 130P is formed, the portion of the lower film 120 exposed through the plurality of openings OP may be removed to form a lower pattern 120P.

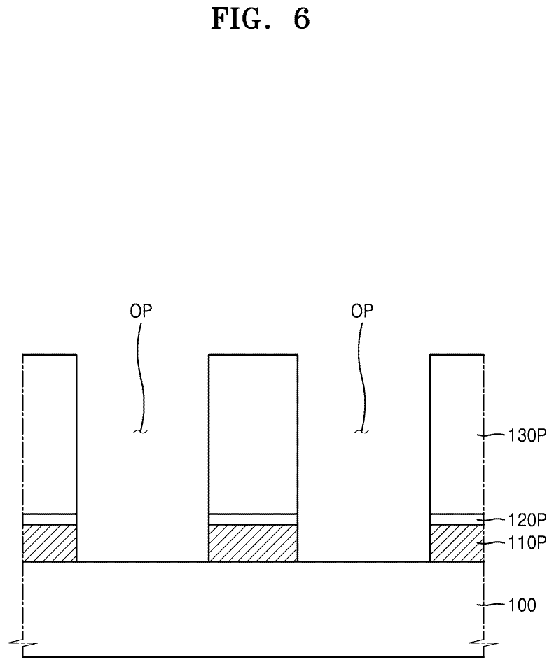

Referring to FIGS. 2 and 6, the feature layer 110 may be processed using the photoresist pattern 130P (P50).

In order to process the feature layer 110, various processes may be performed, such as a process of etching the feature layer 110 exposed through the opening OP of the photoresist pattern 130P, a process of implanting impurity ions into the feature layer 110, a process of forming an additional film on the feature layer 110 through the opening OP, and a process of deforming a part of the feature layer 110 through the opening OP. In FIG. 6, as an example process for processing the lower film 120, a case of forming a feature pattern 110P by etching the feature layer 110 exposed through the opening OP is illustrated.

In other example embodiments, the process of forming the feature layer 110 may be omitted in the process described with reference to FIG. 3, and in this case, instead of operation P50 described with reference to FIGS. 2 and 6, the substrate 100 may be processed using the photoresist pattern 130P. For example, various processes may be performed, such as a process of etching a portion of the substrate 100 using the photoresist pattern 130P, a process of injecting impurity ions into a partial area of the substrate 100, a process of forming an additional film on the substrate 100 through the opening OP, and a process of deforming a portion of the substrate 100 through the opening OP.

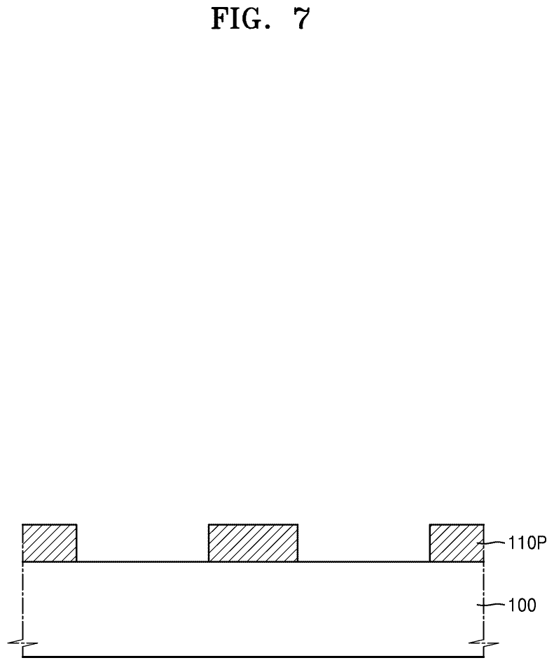

Referring to FIG. 7, the photoresist pattern 130P and the lower pattern 120P remaining on the feature pattern 110P may be removed from the resultant product of FIG. 6. Ashing and stripping processes may be used to remove the photoresist pattern 130P and the lower pattern 120P.

According to the method of manufacturing a semiconductor device according to example embodiments described with reference to FIGS. 2 and 3 to 7, the photoresist composition according to example embodiments used for manufacturing a semiconductor device may include a photosensitive polymer having a main chain including a polyester group. Unlike conventional photoresist compositions, a polyester group included in the main chain of the photosensitive polymer of the photoresist composition according to example embodiments may be decomposed and vaporized through a baking process after exposure. Accordingly, if the photoresist composition according to example embodiments is used, a photoresist pattern may be formed without a development process. Because the development process is omitted, it is possible to prevent the photoresist pattern from collapsing by the developer or the occurrence of defects in the photoresist pattern by particles caused by the developer.

While the inventive concept has been particularly shown and described with reference to embodiments thereof, it will be understood that various changes in form and details may be made therein without departing from the spirit and scope of the following claims.

What is claimed is:

1. A photoresist composition comprising:
a photosensitive polymer having a main chain including a polyester group;
a photoacid generator (PAG); and
a solvent.

2. The photoresist composition of claim 1, wherein
the photosensitive polymer includes repeating units represented by Formula 1; 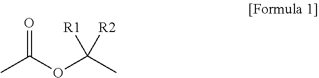
wherein R1 and R2 are each independently a C1 to C5 alkyl group, a C2 to C5 alkenyl group or a phenyl group, or may be connected to each other to form a C3 to C6 cycloalkyl group.

3. The photoresist composition of claim 1, wherein the photosensitive polymer includes repeating units represented by Formula 2; 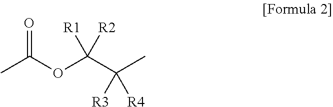
wherein R1, R2, R3 and R4 are each independently a C1 to C5 alkyl group, a C2 to C5 alkenyl group or a phenyl group, and R1 and R2 may be connected to each other to form a C3 to C6 cycloalkyl group, and/or R3 and R4 may be connected to each other to form a C3 to C6 cycloalkyl group.

4. The photoresist composition of claim 1, wherein
the photosensitive polymer includes repeating units represented by Formula 3; 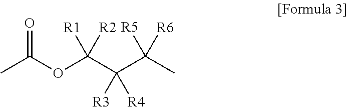
wherein R1, R2, R3, R4, R5 and R6 are each independently a C1 to C5 alkyl group, a C2 to C5 alkenyl group or a phenyl group, and R1 and R2 may be connected to each other to form a C3 to C6 cycloalkyl group, R3 and R4 may be connected to each other to form a C3 to C6 cycloalkyl group, and/or R5 and R6 may be connected to each other to form a C3 to C6 cycloalkyl group.

5. The photoresist composition of claim 1, wherein
the PAG is selected from sulfonium-based PAG, iodonium-based PAG, or nonionic PAG.

6. The photoresist composition of claim 1, wherein
the solvent is selected from propylene glycol methyl ether acetate (1-methoxy-2-propyl acetate, PGMEA), propylene glycol methyl ether (1-methoxy-2-propanol, PGME), ethylene glycol (ethan-1,2-diol, EL), gamma-Butyrolactone (GBA) or diacetone alcohol (DAA).

7. The photoresist composition of claim 1, further comprising a photo-decomposable quencher (PDQ).

8. The photoresist composition of claim 7, wherein the PDQ includes a nitrogen-containing compound having a carboxyl group.

9. A method of manufacturing a semiconductor device, the method comprising:
forming a photoresist film on a feature layer using a photoresist composition including a photosensitive polymer having a main chain including a polyester group, a photoacid generator (PAG), and a solvent;
exposing a first region that is part of the photoresist film;
removing the exposed region of the photoresist film by baking the photoresist film and forming a photoresist pattern including an unexposed region of the photoresist film; and
processing the feature layer using the photoresist pattern.

10. The method of claim 9, wherein the exposing of the first region is performed using extreme ultraviolet (EUV) light.

11. The method of claim 9, wherein the baking of the photoresist film is performed at a temperature in a range from about 100° C. to about 180° C.

12. The method of claim 9, wherein the exposed region of the photoresist film is decomposed and vaporized by the baking.

13. The method of claim 9, wherein the method is devoid of a developing process.

14. The method of claim 9, wherein
the photosensitive polymer includes repeating units represented by Formula 1: 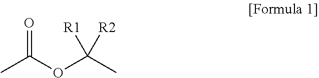
wherein R1 and R2 are each independently a C1 to C5 alkyl group, a C2 to C5 alkenyl group or a phenyl group, or may be connected to each other to form a C3 to C6 cycloalkyl group.

15. The method of claim 9, wherein
the PAG is selected from sulfonium-based PAG, iodonium-based PAG, and nonionic PAG.

16. The method of claim 15, wherein
the solvent is selected from propylene glycol methyl ether acetate (1-methoxy-2-propyl acetate, PGMEA), propylene glycol methyl ether (1-methoxy-2-propanol, PGME), ethylene glycol (ethan-1,2-diol, EL), gamma-Butyrolactone (GBA) and diacetone alcohol (DAA).

17. The method of claim 9, wherein
the photoresist composition further includes a photo-decomposable quencher (PDQ), wherein the PDQ is a nitrogen-containing compound having a carboxyl group.

18. A photoresist composition comprising:
a photosensitive polymer having a main chain including a polyester group;
a photoacid generator (PAG);
a solvent; and
a photo-decomposable quencher (PDQ).

19. The photoresist composition of claim 18, wherein
the photoresist composition is for extreme ultraviolet (EUV) photolithography.

20. The photoresist composition of claim 18, wherein
the photosensitive polymer is vaporized and decomposed by a baking process performed at a temperature in a range from about 100° C. to about 180° C. after exposure to extreme ultraviolet (EUV) light.
